(19) United States
(12) Patent Application Publication
(10) Pub. No.: US 2006/0006524 A1
(43) Pub. Date: Jan. 12, 2006

(54) LIGHT EMITTING DIODE HAVING AN ADHESIVE LAYER FORMED WITH HEAT PATHS

(76) Inventor: Min-Hsun Hsieh, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/160,589

(22) Filed: Jun. 29, 2005

(30) Foreign Application Priority Data
Jul. 7, 2004 (TW) 093120423

(51) Int. Cl. H01L 23/10

(52) U.S. Cl. 257/706; 257/712

(57) ABSTRACT

The present invention is related to a light emitting diode having an adhesive layer provided with heat paths. In the present invention, an adhesive layer is formed to bond the substrate and the LED stack. There are a plurality of metal protrusions or semiconductor protrusions passing through the adhesive layer to form heat-dissipation paths to improve the heat-dissipation effect of the LED so as to enhance the stability and the light-emitting efficiency of the LED.

### BACKGROUND OF THE INVENTION

1. Field of the Invention

This invention relates to an LED having an adhesive layer, and more particularly, to an LED having an adhesive layer formed with a plurality of heat paths.

2. Description of the Related Art

LEDs are widely utilized today, for example, in optical displays, traffic signs, data storage, communication devices, lighting devices, and medical devices. Therefore, increasing the luminance of LEDs is an important consideration in producing LEDs.

U.S. Publication No. 2003/0155579 discloses an LED and the production method thereof. The production method is to form an LED epitaxial structure on a light-absorbing first substrate, and utilize a polymer dielectric adhesive layer to connect the surface of the LED epitaxial structure to a second substrate of high thermal conductivity. This increases the heat-dissipation efficiency of the chip, and increases the light-emitting efficiency of the LED. In the above-mentioned patent, the epitaxial layer is formed on the light-absorbing first substrate and the adhesive layer is utilized to connect the epitaxial layer to the second substrate. Then, the first substrate is removed to reduce the thermal resistance, raise the heat-dissipation efficiency, and raise the light-emitting efficiency. However, because the thermal resistance of the LED is about equal to the sum of thermal resistances of the epitaxial layer, the dielectric adhesive layer, and the second substrate, wherein the thermal conductivity of the dielectric adhesive layer is between 0.1 W/mk and 0.3 W/mk, the LED cannot well utilize the heat-dissipation characteristic of the second substrate of high thermal conductivity. Therefore, the LED has a disadvantage of low heat-dissipation.

### SUMMARY OF THE INVENTION

It is therefore an object of the invention to provide a method of solving the heat-dissipation problem of an LED having an adhesive layer, and a method of solving the heat-dissipation problem of a high-power LED.

In order to solve the above-mentioned disadvantage, the inventor got an inventive concept of providing a plurality of heat paths in the form of a plurality of metal protrusions or semiconductor protrusions passing through or penetrating into the adhesive layer for bonding an LED stack and a substrate so that the heat generated by the LED stack can be dissipated to the substrate through the heat paths. This can efficiently solve the heat-dissipation problem of an LED having an adhesive layer, or of a high power LED.

In order to achieve the above-mentioned object, the present invention discloses an LED having formed with heat paths. The LED comprises a high heat-dissipation substrate, an adhesive layer formed with a plurality of heat path protrusions on the high heat-dissipation substrate, a reflective layer formed on the adhesive layer, an electrical insulation layer formed on the reflective layer, and a transparent conductive layer formed on the electrical insulation layer, wherein the protrusions pass through or penetrate into the adhesive layer to form heat paths. Furthermore, the upper surface of the transparent conductive layer comprises a first surface area and a second surface area. The LED comprises a first contact layer formed on the first surface area, a first cladding layer formed on the first contact layer, a light-emitting layer formed on the first cladding layer, a second cladding layer formed on the light-emitting layer, a second contact layer formed on the second cladding layer, a first wire bonding electrode formed on the second contact layer, and a second wire bonding electrode formed on the second surface area. In addition, another electrical insulation layer can be formed between the high heat-dissipation substrate and the adhesive layer. This is also within the spirit of the present invention.

The above-mentioned high heat-dissipation substrate is made of a material selected from the group consisting of GaP, Si, SiC, and metal.

The above-mentioned heat path protrusions can be in the form of metal heat path protrusions or semiconductor heat path protrusion, the heat path protrusions are made of a material selected from the group consisting of In, Sn, Al, Au, Pt, Zn, Ge, Ag, Ti, Pb, Pd, Cu, AuBe, AuGe, Ni, PbSn, AuZn, GaP, Si, SiC, and the like.

The above-mentioned adhesive layer is made of a material selected from the group consisting of Pi, BCB, PFCB, and the like.

The above-mentioned reflective layer is made of a material selected from the group consisting of In, Sn, Al, Au, Pt, Zn, Ag, Ti, Pb, Pd, Ge, Cu, AuBe, AuGe, Ni, PbSn, and AuZn.

The above-mentioned electrical insulation layer is made of a material selected from the group consisting of SiNx, SiO2, Al2O3, TiO2, and the like.

The above-mentioned transparent conductive layer is made of a material selected from the group consisting of Tin Indium oxide, Tin Cadmium Oxide, Tin Antimony Oxide, Zinc Oxide, and Tin Zinc Oxide.

The above-mentioned first contact layer is made of a material selected from the group consisting of GaP, GaAs, GaAsP, InGaP, AlGaInP, AlGaAs, GaN, InGaN, and AlGaN.

The above-mentioned first cladding layer is made of a material selected from the group consisting of AlGaInP, AlInP, AlN, GaN, AlGaN, InGaN, and AlGaInN.

The above-mentioned light-emitting layer is made of a material selected from the group consisting of AlGaInP, InGaP, GaN, AlGaN, InGaN, and AlGaInN.

The above-mentioned second cladding layer is made of a material selected from the group consisting of AlGaInP, AlInP, AlN, GaN, AlGaN, InGaN, and AlGaInN.

The above-mentioned second contact layer is made of a material selected from the group consisting of GaP, GaAs, GaAsP, InGaP, AlGaInP, AlGaAs, GaN, InGaN, and AlGaN.

The above and other objects of the present invention will become obvious to those of ordinary skill in the art after reading the following detailed description of the preferred embodiments that are illustrated in the accompanying drawings.

### BRIEF DESCRIPTION OF DRAWINGS

FIG. 1 is a diagram of a preferred embodiment of an LED structure in accordance with the present invention.

FIG. 2 is a diagram of another preferred embodiment of an LED structure in accordance with the present invention.

FIG. 3 is a diagram of a yet another preferred embodiment of an LED structure in accordance with the present invention.

### DETAILED DESCRIPTION OF THE INVENTION

### Embodiment 1

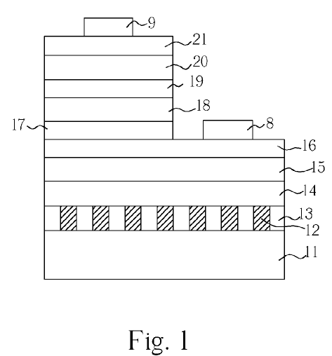

Referring to FIG. 1, an LED comprises a high heat-dissipation substrate 11, an adhesive layer 13 having a plurality of heat path protrusions 12 formed on the high heat-dissipation substrate 11, a reflective layer 14 formed on the adhesive layer 13, an electrical insulation layer 15 formed on the reflective layer 14, and a transparent conductive layer 16 formed on the electrical insulation layer 15, wherein the protrusions 12 pass through or penetrate into the adhesive layer 13 to form heat paths, and the upper surface of the transparent conductive layer 16 comprises a first surface area and a second surface area. The LED further comprises a first contact layer 17 formed on the first surface area, a first cladding layer 18 formed on the first contact layer 17, a light-emitting layer 19 formed on the first cladding layer 18, a second cladding layer 20 formed on the light-emitting layer 19, a second contact layer 21 formed on the second cladding layer 20, a first wire bonding electrode 9 formed on the second contact layer 21, and a second wire bonding electrode 8 formed on the second surface area of the transparent layer 16. Furthermore, another electrical insulation layer can also be formed between the high heat-dissipation substrate and the adhesive layer. This is also within the spirit of the present invention.

### Embodiment 2

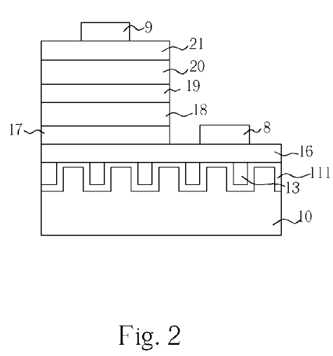

Referring to FIG. 2, an LED comprises a high heat-dissipation substrate 10 having a plurality of heat path protrusions, an electrical insulation layer 111 formed on the high heat-dissipation substrate 10, an adhesive layer 13 formed on the electrical insulation layer 111, and a transparent conductive layer 16 formed on the electrical insulation layer 111 and the adhesive layer 13, wherein the protrusions pass through or penetrate into the adhesive layer 13, and the transparent conductive layer 16 comprises a first surface area and a second surface area. The LED further comprises a first contact layer 17 formed on the first surface area, a first cladding layer 18 formed on the first contact layer 17, a light-emitting layer 19 formed on the first cladding layer 18, a second cladding layer 20 formed on the light-emitting layer 19, a second contact layer 21 formed on the second cladding layer 20, a first wire bonding electrode 9 formed on the second contact layer 21, and a second wire bonding electrode 8 formed on the second surface area of the transparent conductive layer 16.

### Embodiment 3

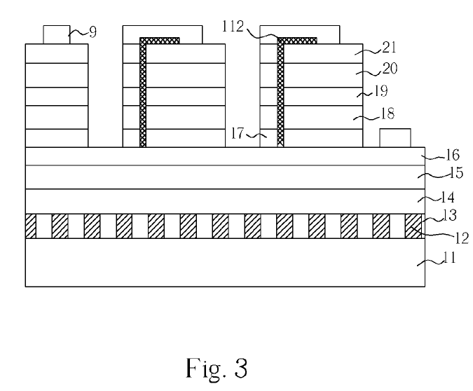

Referring to FIG. 3, which is a diagram of another preferred embodiment of an LED providing with an adhesive layer formed with a plurality of heat paths in accordance with the present invention. This embodiment is quite similar to embodiment 1. The difference between them lies in that the upper surface of the electrical insulation layer 15 comprises a plurality of first surface areas and a plurality of second surface areas, and a plurality of transparent conductive layers 16 are respectively formed on the first surface areas of the electrical insulation layer 15. Furthermore, the upper surfaces of the transparent conductive layers 16 comprise a plurality of first surface areas and a plurality of second surface areas, and a plurality of LED stacking layers are respectively formed on the first surface areas of the transparent conductive layers. In addition, the LED stack comprises a first contact layer 17, a first cladding layer 18, a light-emitting layer 19, a second cladding layer 20, a second contact layer 21, an electrical insulation layer 112 formed on the second surface area of the electrical insulation layer 15 and the LED stack, an electrode 7 formed on the second surface areas of the transparent conductive layers 16 and connected to the second contact layer 21 of the adjacent LED stack, a first wire bonding electrode 9 formed on a specific second contact layer 21, and a second wire bonding electrode 8 formed on a second surface area of a specific transparent conductive layer 16. The above-mentioned LED stacks are electrically connected to each other by demands to form an LED array.

The above-mentioned high heat-dissipation substrate is made of a material selected from the group consisting of GaP, Si, SiC, and metal.

The above-mentioned heat path protrusion can be a metal heat path protrusion or a semiconductor heat path protrusion, where the heat path protrusion is made of a material selected from the group consisting of In, Sn, Al, Au, Pt, Zn, Ge, Ag, Ti, Pb, Pd, Cu, AuBe, AuGe, Ni, PbSn, AuZn, GaP, Si, SiC, and the like.

The above-mentioned adhesive layer is made of a material selected from the group consisting of Pi, BCB, PFCB, and the like.

The above-mentioned reflective layer is made of a material selected from the group consisting of In, Sn, Al, Au, Pt, Zn, Ag, Ti, Pb, Pd, Ge, Cu, AuBe, AuGe, Ni, PbSn, and AuZn.

The above-mentioned electrical insulation layer is made of a material selected from the group consisting of SiNx, SiO2, Al2O3, TiO2, and the like.

The above-mentioned transparent conductive layer is made of a material selected from the group consisting of Tin Indium oxide, Tin Cadmium Oxide, Tin Antimony Oxide, Zinc Oxide, and Tin Zinc Oxide.

The above-mentioned first contact layer is made of a material selected from the group consisting of GaP, GaAs, GaAsP, InGaP, AlGaInP, AlGaAs, GaN, InGaN, and AlGaN.

The above-mentioned first cladding layer is made of a material selected from the group consisting of AlGaInP, AlInP, AlN, GaN, AlGaN, InGaN, and AlGaInN.

The above-mentioned light-emitting layer is made of a material selected from the group consisting of AlGaInP, InGaP, GaN, AlGaN, InGaN, and AlGaInN.

The above-mentioned second cladding layer is made of a material selected from the group consisting of AlGaInP, AlInP, AlN, GaN, AlGaN, InGaN, and AlGaInN.

The above-mentioned second contact layer is made of a material selected from the group consisting of GaP, GaAs, GaAsP, InGaP, AlGaInP, AlGaAs, GaN, InGaN, and AlGaN.

Those skilled in the art can readily understand that numerous modifications and alterations of the device and method may be made within the scope and spirit of the invention. Accordingly, the above disclosure should be construed as limited only by the metes and bounds of the appended claims.

What is claimed is:

1. An light-emitting diode having an adhesive layer formed with at leat one heat path comprising:
a high heat-dissipation substrate;
an electrical insulation layer;
an LED stack formed on the electrical insulation layer; and
an adhesive layer between the high heat-dissipation substrate and the electrical insulation layer, wherein the adhesive layer is formed with at least one heat path protrusion that passes through or penetrate the adhesive layer.

2. The light-emitting diode according to claim 1, further comprising an electrical insulation layer formed between the high heat-dissipation substrate and the adhesive layer, or an electrical insulation layer simultaneously formed between the high heat-dissipation substrate and the adhesive layer and formed between the adhesive layer and the LED stack.

3. The light-emitting diode according to claim 2, wherein the electrical insulation layer is made of a material selected from the group consisting of SiNx, SiO2, Al2O3, TiO2, and the like.

4. The light-emitting diode according to claim 1, wherein the electrical insulation layer is made of a material by selected from the group consisting of SiNx, SiO2, Al2O3, TiO2, and the like.

5. The light-emitting diode according to claim 1 further comprising: a transparent conductive layer formed between the electrical insulation layer and the LED stack.

6. The light-emitting diode according to 5, wherein the transparent conductive layer is made of a material selected from the group consisting of tin indium oxide, tin cadmium oxide, tin antimony oxide, zinc oxide, and tin zinc oxide.

7. The light-emitting diode according to claim 1 further comprising: a transparent layer formed on the LED stack.

8. The light-emitting diode according to claim 7, wherein the transparent conductive layer is made of a material selecting from the group consisting of tin indium oxide, tin cadmium oxide, tin antimony oxide, zinc oxide, and tin zinc oxide.

9. The light-emitting diode according to claim 1 further comprising: a reflective layer formed between the adhesive layer and the electrical insulation layer.

10. The light-emitting diode according to claim 9, wherein the reflective layer is made of a material selected from the group consisting of In, Sn, Al, Au, Pt, Zn, Ag, Ti, Pb, Pd, Ge, Cu, AuBe, AuGe, Ni, PbSn, and AuZn.

11. The light-emitting diode according to claim 1, wherein the protrusion heat path is capable of being a metal protrusion path or a semiconductor heat path, and wherein the heat path is made of a material selected from the group consisting of In, Sn, Al, Au, Pt, Zn, Ge, Ag, Ti, Pb, Pd, Cu, AuBe, AuGe, Ni, PbSn, AuZn, GaP, Si, SiC, and the like.

12. The light-emitting diode according to claim 1, wherein the adhesive layer is made of a material selected from the group consisting of Pi, BCB, PFCB, and the like.

13. The light-emitting diode according to claim 1, wherein the high heat-dissipation substrate is made of a material by selected from the group consisting of GaP, Si, SiC, and the like.

14. The light-emitting diode according to claim 1, wherein the LED stack comprises:
a first contactive layer;
a first cladding layer formed on the first contactive layer;
a light-emitting layer formed on the first cladding layer;
a second cladding layer formed on the light-emitting layer; and
a second contact layer formed on the second cladding layer.

15. The light-emitting diode according to claim 14, wherein the first contact layer is made of a material selected from the group consisting of GaP, GaAs, GaAsP, InGaP, AlGaInP, AlGaAs, GaN, InGaN, and AlGaN.

16. The light-emitting diode according to claim 14, wherein the first cladding layer is made of a material selected from the group consisting of AlGaInP, AlInP, AlN, GaN, AlGaN, InGaN, and AlGaInN.

17. The light-emitting diode according to claim 14, wherein the light-emitting layer is made of a material selected from the group consisting of AlGaInP, InGaP, GaN, AlGaN, InGaN, and AlGaInN.

18. The light-emitting diode according to claim 14, wherein the second cladding layer is made of a material selected from the group consisting of AlGaInP, AlInP, AlN, GaN, AlGaN, InGaN, and AlGaInN.

19. The light-emitting diode according to claim 14, wherein the second contact layer is made of a material selected from the group consisting of GaP, GaAs, GaAsP, InGaP, AlGaInP, AlGaAs, GaN, InGaN, and AlGaN.

20. An LED array providing with an adhesive layer having a heat path comprising:
a high heat-dissipation substrate;
an electrical insulation layer;
a plurality of LED stacks formed on the electrical insulation layer, wherein said LED stacks on the electrical insulation layer are electrically contacting to form an LED array; and
an adhesive layer between the high heat-dissipation substrate and the electrical insulation layer, wherein the adhesive layer has a heat path protrusion so as to use the protrusion to pass through or partially pass through the adhesive layer.

21. The LED array according to claim 20 further comprising: an electrical insulation layer formed between the high heat-dissipation substrate and the adhesive layer, or an electrical insulation layer simultaneously formed between the high heat-dissipation substrate and the adhesive layer and formed between the adhesive layer and said LED stacks.

22. The LED array according to claim 21, wherein the electrical insulation layer is made of a material selected from the group consisting of SiNx, SiO2, Al2O3, TiO2, and the like.

23. The LED array according to claim 20, wherein the electrical insulation layer is made of a material selected from the group consisting of SiNx, SiO2, Al2O3, TiO2, and the like.

24. The LED array according to claim 20 further comprising a transparent conductive layer formed between the electrical insulation layer and the LED stack.

25. The LED array according to claim 20 further comprising a transparent layer formed on the LED stack.

26. The LED array according to claim 20 further comprising a reflective layer formed between the adhesive layer and the electrical insulation layer.

27. The LED array according to claim 20, wherein the protrusion heat path is capable of being a metal protrusion path or a semiconductor heat path, and wherein the heat path is made of a material selected from the group consisting of In, Sn, Al, Au, Pt, Zn, Ge, Ag, Ti, Pb, Pd, Cu, AuBe, AuGe, Ni, PbSn, AuZn, GaP, Si, SiC, and the like.

28. The LED array according to claim 20, wherein the adhesive layer is made of a material selected from the group consisting of Pi, BCB, PFCB, and the like.

29. The LED array according to claim 20, wherein the high heat-dissipation substrate is made of a material selected from the group consisting of GaP, Si, SiC, the like.

30. The LED array according to claim 20, wherein the LED stack comprises:
a first contactive layer;
a first cladding layer formed on the first contactive layer;
a light-emitting layer formed on the first cladding layer;
a second cladding layer formed on the light-emitting layer; and
a second contact layer formed on the second cladding layer.

31. The LED array according to claim 30, wherein the first contact layer is made of a material selected from the group consisting of GaP, GaAs, GaAsP, InGaP, AlGaInP, AlGaAs, GaN, InGaN, and AlGaN.

32. The LED array according to claim 30, wherein the first cladding layer is made of a material selected from the group consisting of AlGaInP, AlInP, AlN, GaN, AlGaN, InGaN, and AlGaInN.

33. The LED array according to claim 30, wherein the light-emitting layer is made of a material selected from the group consisting of AlGaInP, InGaP, GaN, AlGaN, InGaN, and AlGaInN.

34. The LED array according to claim 30, wherein the second cladding layer is made of a material selected from the group consisting of AlGaInP, AlInP, AlN, GaN, AlGaN, InGaN, and AlGaInN.

35. The LED array according to claim 30, wherein the second contact layer is made of a material selected from the group consisting of GaP, GaAs, GaAsP, InGaP, AlGaInP, AlGaAs, GaN, InGaN, and AlGaN.
